(19) United States
(12) Patent Application Publication
(10) Pub. No.: US 2011/0027950 A1
(43) Pub. Date: Feb. 3, 2011

(54) METHOD FOR FORMING A SEMICONDUCTOR DEVICE HAVING A PHOTODETECTOR

(76) Inventors: Robert E. Jones, Austin, TX (US); Dean J. Denning, Del Valle, TX (US); Gregory S. Spencer, Pflugerville, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/510,358

(22) Filed: Jul. 28, 2009

(51) Int. Cl. H01L 27/12

(52) U.S. Cl. 438/155; 257/E27.112

(57) ABSTRACT

A method is provided for integrating a germanium photodetector with a CMOS circuit. The method comprises: forming first and second isolation regions in a silicon substrate; forming a gate electrode in the first isolation region; implanting source/drain extensions in the silicon substrate adjacent to the gate electrode; forming a first sidewall spacer on the gate electrode; implanting source/drain regions in the silicon substrate; removing the first sidewall spacer from the gate electrode; forming a first protective layer over the first and second isolation regions; removing a portion of the first protective layer to form an opening over the second isolation region; forming a semiconductor material comprising germanium in the opening; forming a second protective layer over the first and second isolation regions; selectively removing the first and second protective layers from the first isolation region; and forming contacts to the transistor and to the semiconductor material.

### BACKGROUND

1. Field

This disclosure relates generally to semiconductors, and more specifically, to a method of forming a semiconductor device having a photodetector.

2. Related Art

Germanium (Ge) photodetectors are used in optical communications to convert light in, for example, the 1310 nanometer (nm) and 1550 nm wavelength bands to electrical signals. Germanium photodetectors have been integrated with complementary metal-oxide semiconductor (CMOS) circuits on the same silicon (Si) substrate. However, as CMOS devices are scaled to have smaller geometries and to operate at higher speeds, process integration of Ge photodetectors and CMOS circuits becomes more difficult.

Therefore, what is needed is a method that solves the above problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIGS. 1-6 illustrate cross-sectional views of a semiconductor device during formation of an optical device and an electrical device in accordance with a first embodiment.

FIGS. 7-12 illustrate cross-sectional views of a semiconductor device during formation of an optical device and an electrical device in accordance with a second embodiment.

### DETAILED DESCRIPTION

Generally, there is provided, a semiconductor and method for forming the semiconductor having a Ge photodetector and CMOS electrical circuit on the same substrate. The method includes forming disposable sidewall spacers on the gate stacks of CMOS transistors. The disposable sidewall spacers allow metal source/drain contacts to be formed more closely to the gate. Also, the method includes the formation of a Nickel (Ni) salicide, a Platinum (Pt) salicide, or a combination of Ni and Pt salicide for making the source/drain contacts. The Ni and Pt salicide can be formed using a lower temperature than Cobalt (Co). Also, the resulting CMOS transistor can operate at a higher switching speed.

In one aspect, there is provided, a method comprising: providing a silicon substrate; forming a first isolation region in the silicon substrate; forming a second isolation region in the silicon substrate; forming a gate electrode for a transistor in the first isolation region; implanting source/drain extensions in the silicon substrate adjacent to the gate electrode; forming a first sidewall spacer on a side of the gate electrode; implanting source/drain regions in the silicon substrate adjacent to the gate electrode; removing the first sidewall spacer from the side of the gate electrode; forming a first protective layer over the first and second isolation regions of the silicon substrate; removing a portion of the first protective layer to form an opening over the second isolation region; forming a semiconductor material comprising germanium in the opening; forming a second protective layer over the first and second isolation regions of the silicon substrate; selectively removing the first and second protective layers from the first region; and forming contacts to the transistor and to the semiconductor material. The step of providing a silicon substrate may further comprise providing a silicon-on-insulator substrate. The step of forming the first protective layer may further comprise forming the first protective layer comprising silicon dioxide. Forming the second protective layer may further comprise forming the second protective layer comprising silicon nitride. Forming a semiconductor material comprising germanium may further comprise selectively depositing epitaxial germanium. The step of selectively removing the first and second protective layers may further comprise forming a second sidewall spacer on the gate electrode with a portion of the first protective layer. The method may further comprise selectively saliciding the source/drain regions and the gate electrode to form a salicide comprising a metal selected from a group consisting of nickel and platinum. The method may further comprise forming a stressor layer over the first isolation region after the step of selectively removing the first and second protective layers. The step of forming the first protective layer may further comprise the steps of: forming a silicon nitride layer on the first and second isolation regions; and forming a silicon dioxide layer on the silicon nitride layer. The first isolation region may be formed using shallow trench isolation.

In another aspect, there is provided, a method comprising: providing a silicon substrate; forming a first isolation region in the silicon substrate; forming a second isolation region in the silicon substrate; forming a gate electrode for a transistor in the first isolation region; implanting source/drain extensions in the silicon substrate adjacent to the gate electrode; forming a first sidewall spacer on a side of the gate electrode; forming a second sidewall spacer adjacent to the first sidewall spacer, the second sidewall spacer being L-shaped; forming a third sidewall spacer on the L-shaped second sidewall spacer; implanting source/drain regions in the silicon substrate adjacent to the gate electrode; removing the third sidewall spacer; forming a first protective layer over the first and second isolation regions of the silicon substrate; removing a portion of the first protective layer to form an opening over the second isolation region; forming a semiconductor material comprising germanium in the opening; forming a second protective layer over the first and second isolation regions of the silicon substrate; selectively removing the first and second protective layers from the first region; and forming contacts to the transistor and to the semiconductor material. The step of providing a silicon substrate may further comprise providing a silicon-on-insulator substrate. The step of forming the first protective layer may further comprise forming the first protective layer comprising silicon dioxide. The step of forming the second protective layer may further comprise forming the second protective layer comprising silicon nitride. The step of forming a semiconductor material comprising germanium may further comprise selectively depositing epitaxial germanium. The method may further comprise selectively saliciding the source/drain regions and the gate electrode to form a salicide comprising a metal selected from a group consisting of nickel and platinum. The method may further comprise forming a stressor layer over the first isolation region after the step of selectively removing the first and second protective layers. The step of forming the first protective layer may further comprise the steps of: forming a silicon nitride layer on the first and second isolation regions; and forming a silicon dioxide layer on the silicon nitride layer. The first and second isolation regions may be formed using shallow trench isolation. The method may further comprise forming doped regions in the semiconductor material comprising germanium.

The semiconductor substrate described herein can be any semiconductor material or combinations of materials, such as gallium arsenide, silicon germanium, silicon-on-insulator (SOI), silicon, monocrystalline silicon, the like, and combinations of the above.

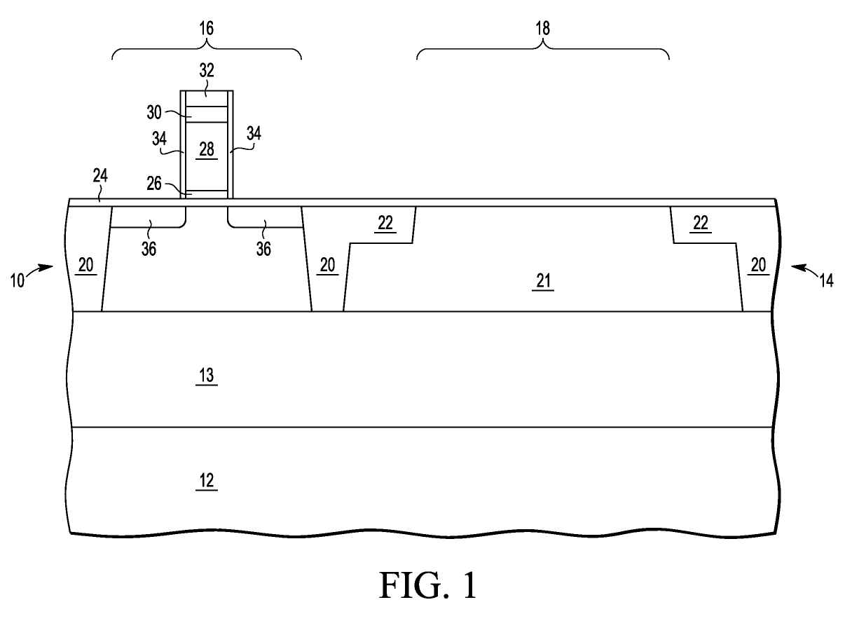

FIGS. 1-6 illustrate cross-sectional views of a semiconductor device 10 during formation of an optical device and an electrical device in accordance with a first embodiment. FIG. 1 illustrates a cross-sectional view of semiconductor device 10 after a gate electrode has been formed. In the illustrated embodiment, semiconductor device 10 includes a photonic silicon-on-insulator (SOI) substrate having a first silicon layer 12, a buried oxide layer 13, and a second silicon layer 14. In another embodiment, the substrate may comprise bulk silicon. Shallow trench isolation (STI) regions are formed in second silicon layer 14. A first STI region 16 is bounded by trench 20 and a second STI region 18 is bounded by trench 22. Trench 20 extends through the entire thickness of second silicon layer 14. Trench 22 is shallower than trench 20 in the illustrated embodiment. Shallow trench isolation region 16 is for CMOS circuit elements. Shallow trench isolation region 18 is for one or more optical elements, such as for example, a photodetector. A portion of second silicon layer 14 within STI region 18 functions as a waveguide 21. In another embodiment, the deeper STI region 16 may also be formed within portions of the second STI region 18 in conjunction with STI 22 for forming desired optical and optoelectronic devices and for electrical isolation of optoelectronic devices.

A gate dielectric layer 24 is formed over second silicon layer 14. The gate dielectric 24 can be formed from any dielectric material such as silicon dioxide or a high dielectric constant (high k) material, such as hafnium oxide. A gate stack comprising a gate electrode 26, a polysilicon layer 28, an oxide layer 30, and a nitride layer 32 formed over second silicon layer 14 using conventional semiconductor processing techniques. The gate electrode 26 may be any conductive material such as metal or polycrystalline silicon, also known as polysilicon. The polysilicon layer 28 is formed on the gate electrode 26. As is known in the art, the polysilicon layer 28 and any polysilicon in the gate electrode 26 can be formed by deposition of an amorphous silicon layer which is converted to polysilicon by subsequent thermal processes. The oxide layer 30 is formed on the polysilicon layer 28. A silicon nitride layer 32 is formed over oxide layer 30. The gate stack is then patterned using a conventional photolithographic defined etch process. Sidewall spacers 34 are formed on the gate stack. Preferably, sidewall spacers 34 are silicon nitride. Oxide layer 30 functions as an etch stop layer when nitride layer 32 is removed later in the process. The gate stack and sidewall spacers 34 function as a mask for extension implants 36. The particular implant used for extension implants 36 depends on the particular transistor type being formed, which may be either a P-channel or N-channel transistor.

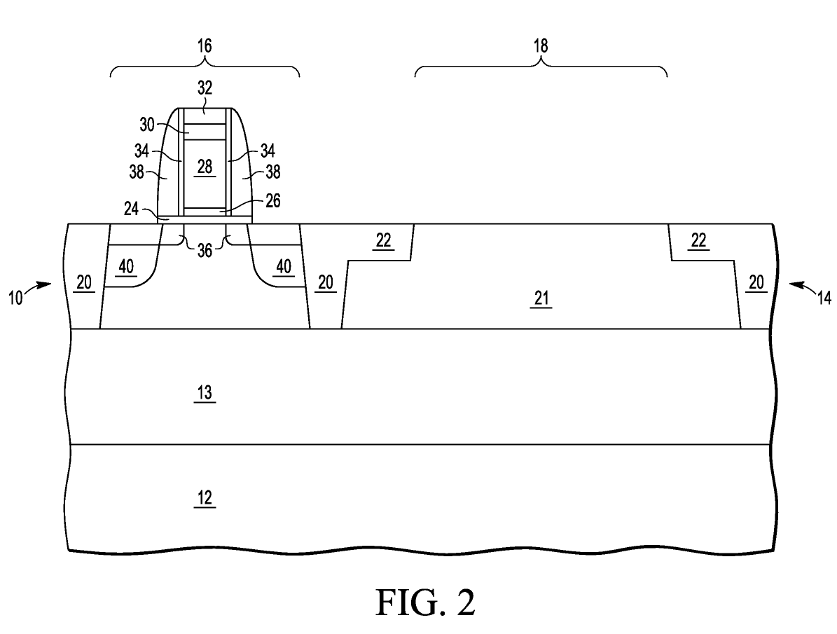

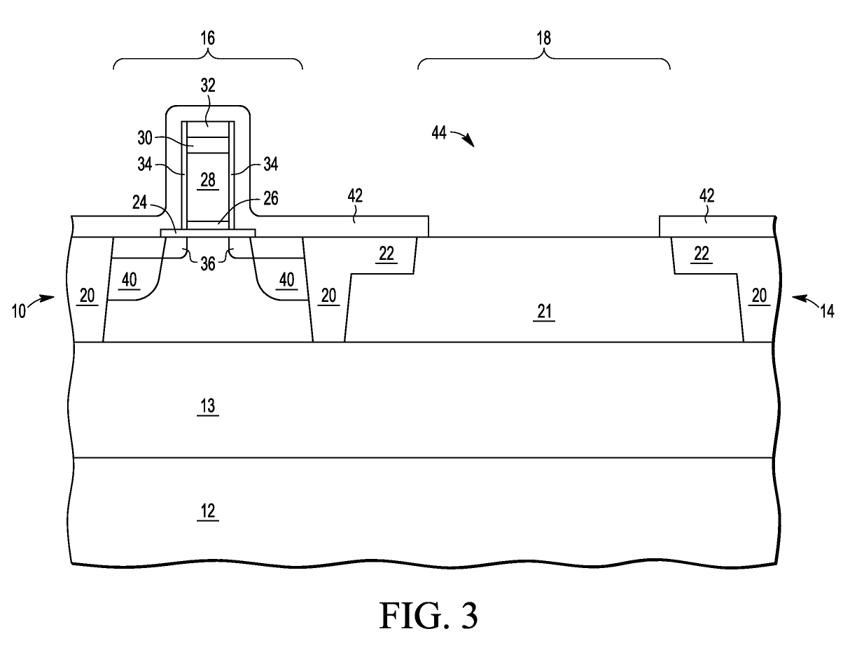

FIG. 2 illustrates a cross-sectional view of semiconductor device 10 after source/drain regions 40 have been formed. Prior to implanting deep source/drain regions 40, sidewall spacers 38 are formed on the sides of the gate stack using a conventional process. Sidewall spacers 38 may be formed of a dielectric material such as silicon oxide. Exposed portions of gate dielectric 24 are then removed using an anisotropic etch. The deep source/drain implants 40 are aligned using sidewall spacers 38 as a mask. The type of implant depends on the type of transistor being formed. Following source/drain implantation, sidewall spacers 38 are then removed using an etch process that selectively etches sidewall spacers 38 while leaving sidewall spacers 34 as illustrated in FIG. 3.

FIG. 3 illustrates a cross-sectional view of semiconductor device 10 after a first semiconductor protective layer 42 is formed and patterned. The first protective layer 42 protects second silicon layer 14 in first isolation region 16 during processing related to second isolation region 18. The first protective layer 42 may be formed by any suitable process, such as chemical vapor deposition (CVD), atomic layer deposition (ALD), physical vapor deposition (PVD), and combinations of the above. The first protective layer 42 is patterned using conventional patterning techniques to expose windows or openings in the second isolation region 18, such as for example, opening 44. Opening 44 exposes a surface of the underlying second silicon layer 14. Note that in another embodiment a portion of the underlying silicon layer 14 in opening 44 may be removed during the patterning process.

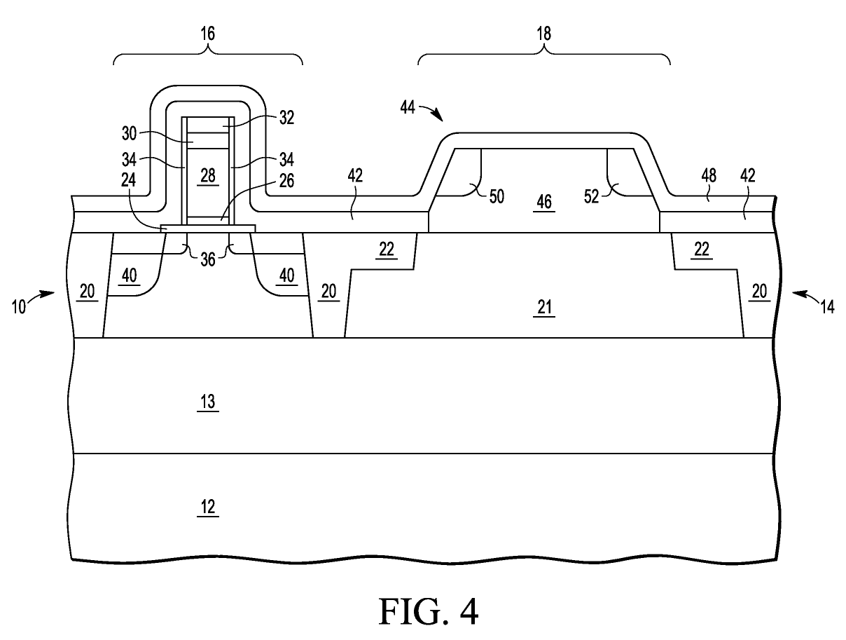

FIG. 4 illustrates a cross-sectional view of semiconductor device 10 after a second semiconductor protective layer 48 is formed. After forming opening 44 in the first protective layer 42, a semiconductor material 46 comprising germanium is formed in opening 44 to provide a photodetector. In one embodiment, semiconductor material 46 is germanium. Second protective layer 48 is a germanium protective layer. The germanium 46 is formed by epitaxial growth in opening 44 and preferably by a selective epitaxial growth process. Prior to the germanium growth process, it is desirable to perform a preclean so germanium can be better grown in opening 44. In one embodiment, the preclean exposes opening 44 to hydrogen for approximately 5 minutes at approximately 800 degrees Celsius. After the preclean, a germanium growth process is performed. During the germanium growth process, first protective layer 42 prevents germanium growth on the other areas of semiconductor device 10. In one embodiment, the germanium is grown by exposing semiconductor device 10 to a GeH₄ species at a temperature of approximately 400-600 degrees Celsius. Note that because the anneal temperature for the source/drain regions 40 is greater than the melting temperature of germanium, the anneal should be done before the germanium is grown. After forming semiconductor material 46, the second protective layer 48 is formed. The second protective layer 48 can be formed by any process such as CVD, ALD, PVD and combinations thereof. In one embodiment, second protective layer 48 is a germanium protective layer that includes silicon and nitrogen, such as silicon nitride, silicon-rich silicon nitride, or silicon oxynitride. Following the formation of second protective layer 48, implanted dopant regions may be formed in semiconductor material 46 using conventional lithographically defined implant masks. In one embodiment, implanted dopant region 50 is an N-type dopant and implant dopant region 52 is a P-type dopant. Also, in the illustrated embodiment, semiconductor material 46, as doped, forms a photodetector device. In addition, in the illustrated embodiment, two mask and implant processes are used followed by one anneal process to form regions 50 and 52.

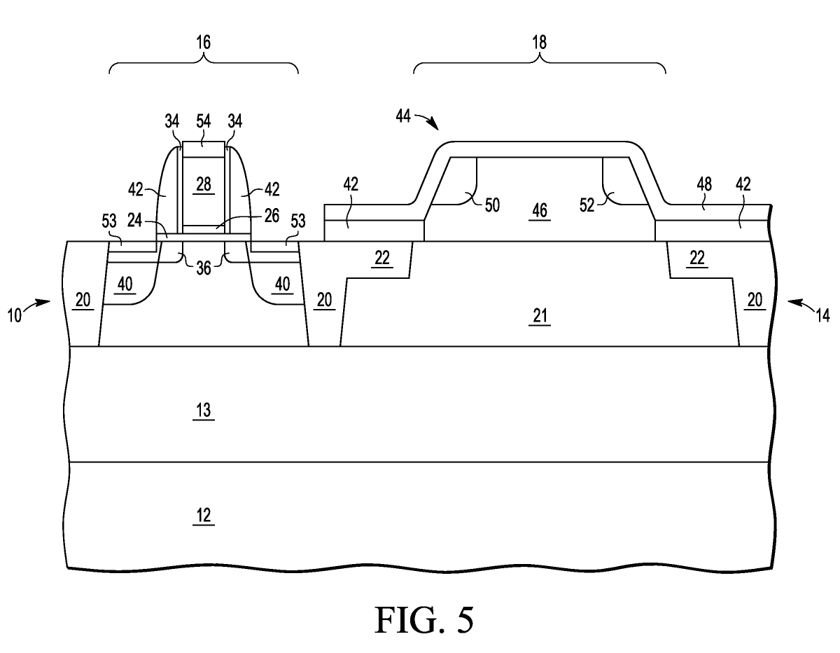

FIG. 5 illustrates a cross-sectional view of semiconductor device 10 after the first protective layer 42 and the second protective layer 48 are patterned. The first and second protective layers only need to be removed for first isolation region 16 to allow for salicidation. The second protective layer 48 remains over semiconductor material 46 to protect it from salicidation. The first and second protective layers are removed from almost all portions of first isolation region 16 except for the sidewalls of the gate electrode resulting in sidewall spacers 42. The isolation region 16 is exposed to an etching chemistry with a high degree of anisotropy. The anisotropic etch is used to prevent the undesirable removal of spacers 42. In the illustrated embodiment, this etch also removes silicon nitride layer 32 and oxide layer 30 from the gate. After patterning the first and second protective layers, the exposed silicon portions are salicided to form salicide 53 in the source/drain regions 40 and salicide 54 on top of the gate stack. Note that as used herein, salicide means selective silicide or self-aligned silicide. Salicide 53 and 54 are formed by depositing a metal including nickel or platinum using CVD, ALD, PVD, or combinations thereof. Semiconductor device 10 is then heated by a first anneal in order for some portion of the nickel or platinum to react with the exposed silicon in the gate electrode and in the source/drain regions. Unreacted nickel or platinum is removed by exposure to a chemical reactant. A second anneal may optionally be used to complete the desired reaction between the nickel or platinum and silicon. The first anneal and the second anneal, if used, are limited to approximately 425 degrees Celsius or below. The salicide temperature for nickel and platinum is lower than the salicide temperatures of cobalt and lower than the anneal temperatures for doped regions 50 and 52.

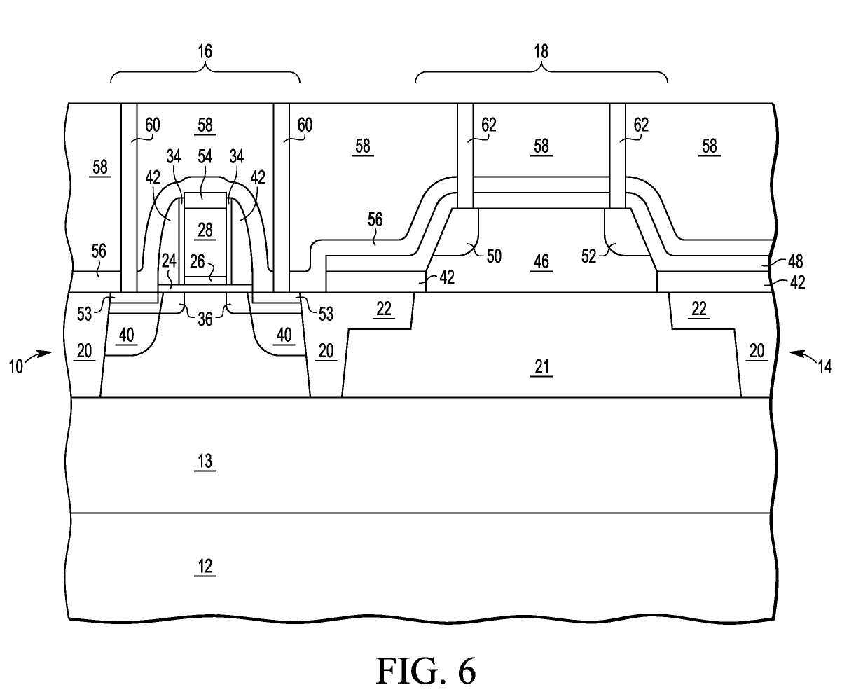

FIG. 6 illustrates a cross-sectional view of semiconductor device 10 after an interlevel dielectric (ILD) layer 58 and contacts 60 and 62 are formed. A stressor layer 56 is first formed over semiconductor device 10. In one embodiment, stressor layer 56 is an etch stop layer (ESL) that provides compressive stress for P-channel transistors and relaxed stress for N-channel transistors. Silicon nitride may be used for a stressor layer 56 that provides compressive stress. The silicon nitride may be formed by CVD, ALD, PVD, or combinations thereof. The ILD layer 58 is formed by CVD and planarized using a chemical mechanical polishing (CMP) process. Contact openings are formed in ILD layer 58. In one embodiment, contacts 60 and 62 are formed from tungsten. In other embodiments, contact 60 and 62 may be formed from another metal such as aluminum or copper.

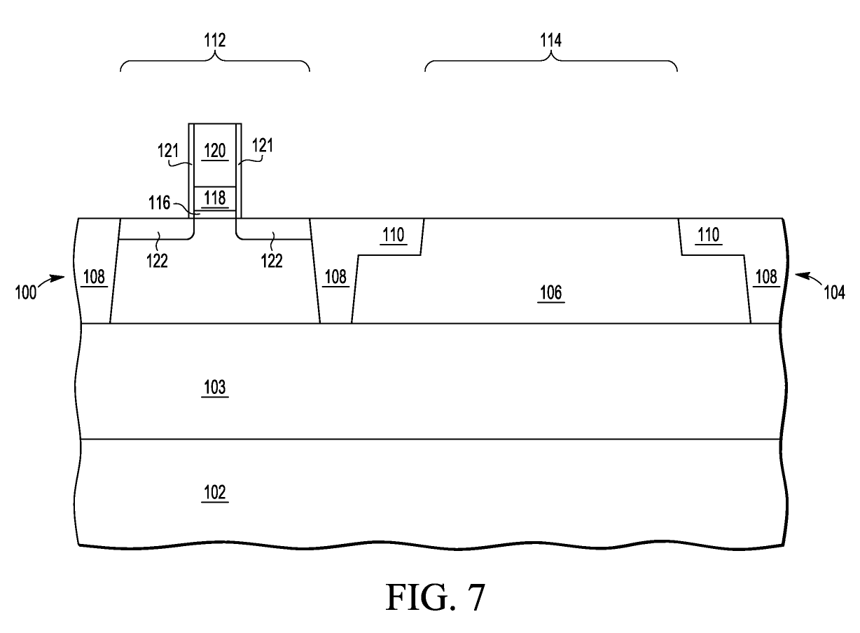

FIGS. 7-12 illustrate cross-sectional views of a semiconductor device 100 during formation of an optical device and an electrical device in accordance with a second embodiment. FIG. 7 illustrates cross-sectional views of semiconductor device 100 after a gate electrode has been formed. In the illustrated embodiment, semiconductor device 100 includes a photonic silicon-on-insulator (SOI) substrate having a first silicon layer 102, a buried oxide layer 103, and a second silicon layer 104. In another embodiment, the substrate may comprise bulk silicon. Shallow trench isolation (STI) regions are formed in second silicon layer 104. A first STI region 112 is bounded by trench 108 and a second STI region 114 is bounded by trench 110. Trench 108 extends through the entire thickness of second silicon layer 104. Trench 110 is shallower than trench 108. Shallow trench isolation region 112 is for CMOS circuit elements. Shallow trench isolation region 114 is for one or more optical elements, such as for example, a photodetector. A portion of second silicon layer 104 within STI region 114 functions as a waveguide 106. In another embodiment, the deeper STI region 112 may also be formed within portions of the second STI region 114 in conjunction with STI 110 for forming desired optical and optoelectronic devices and for electrical isolation of optoelectronic devices.

A gate dielectric layer 116 is formed on second silicon layer 104. The gate dielectric 116 can be any dielectric such as silicon dioxide or a high dielectric constant (high k) material, such as hafnium oxide. A gate electrode 118 may be any conductive material such as metal or polysilicon. A polysilicon layer 120 is formed on the gate electrode 118. The gate dielectric layer 110, gate electrode 118, and polysilicon layer 120 are then patterned to form a gate stack. Sidewall spacers 121 are formed on the gate stack. Preferably, sidewall spacers 121 are nitride zero spacers formed from silicon nitride. Nitride zero spacers 121 are formed using a relatively conformal deposition followed by an anisotropic etch back which is typical for sidewall spacer formation. Nitride zero spacers 121 are substantially unaffected by etchants used for etching oxide. Also, nitride zero spacers 121 function as a diffusion barrier for metal gate 118 and gate dielectric 116. The gate stack and sidewall spacers 121 function as a mask for extension implants 122. The particular implant depends on the transistor being formed, which may be either a P-channel or N-channel transistor.

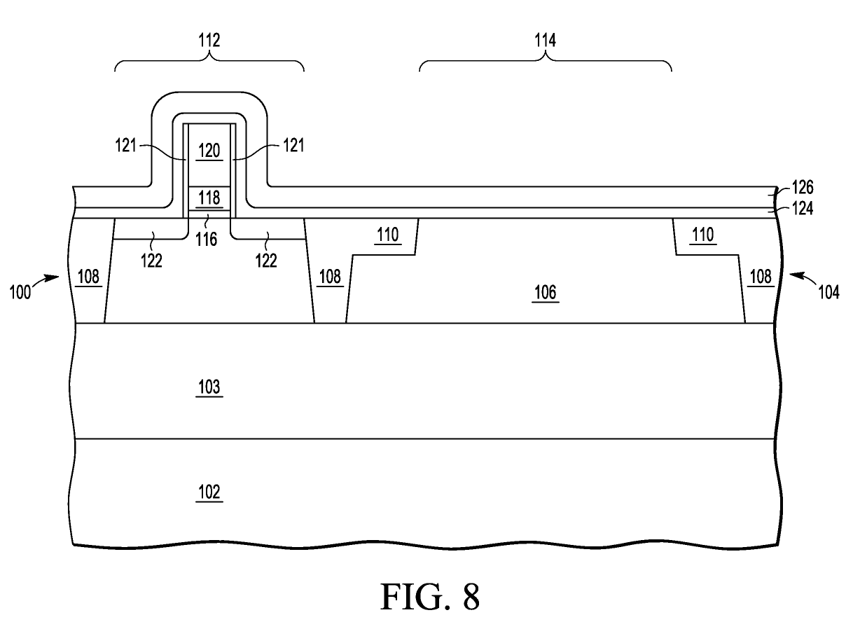

FIG. 8 illustrates cross-sectional views of semiconductor device 100 after formation of oxide layer 124 and nitride layer 126. Oxide layer 124 is deposited on the surface of second silicon layer 104 and on the gate stack, followed by deposition of nitride layer 126.

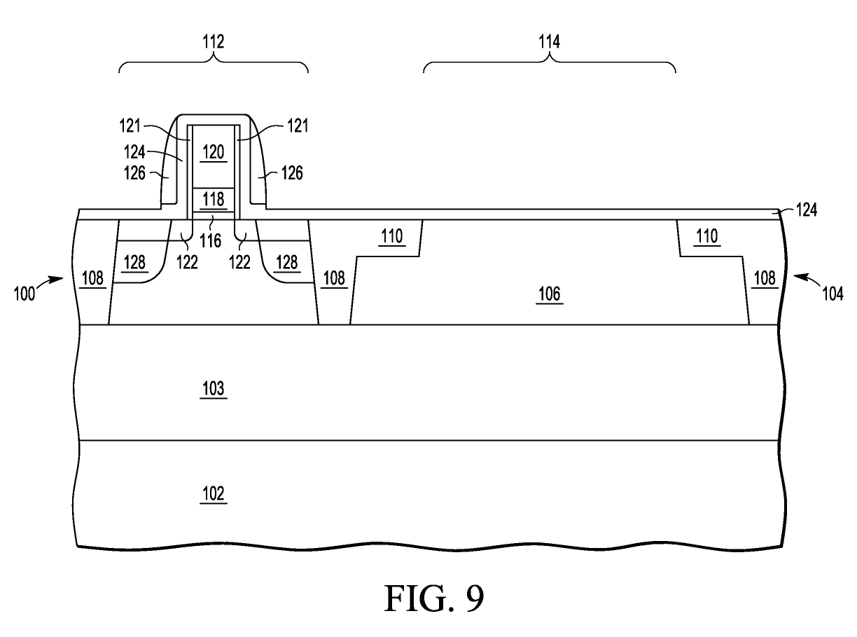

FIG. 9 illustrates cross-sectional views of semiconductor device 100 after sidewall spacers are formed from remaining portions of oxide layer 124 and nitride layer 126. Oxide layer 124 and nitride layer 126 are etched to remove most of nitride layer 126 except a thin disposable source/drain spacer 126 over the silicon regions adjacent to the gate stack and oxide layer 124 is etched leaving a thinned residual oxide liner over the silicon regions and over the top of the gate stack and an unthinned L-shaped sidewall spacer 124. The deep source/drain implants 128 are aligned using sidewall spacers 124 and 126 as a mask. The type of implant depends on the type of transistor being formed.

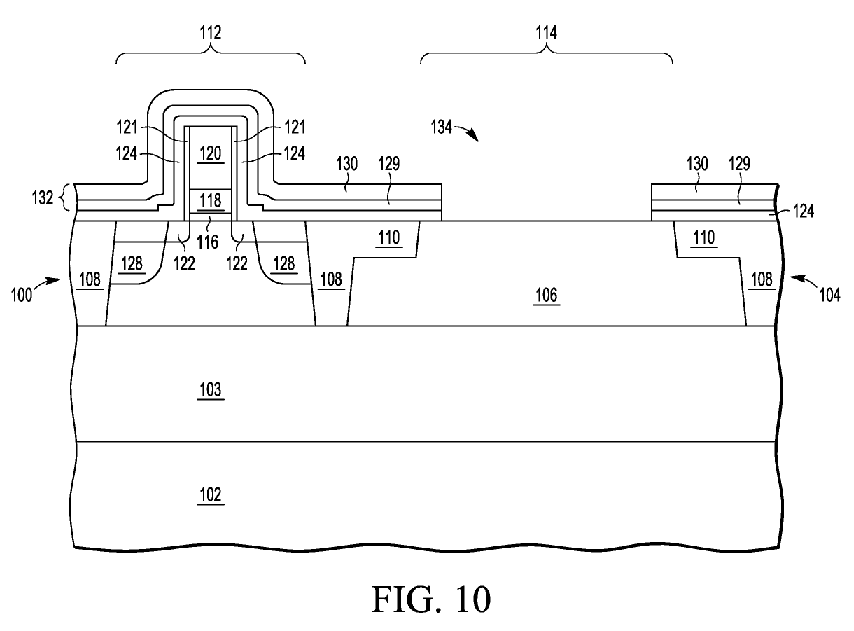

FIG. 10 illustrates cross-sectional views of semiconductor device 100 after a first semiconductor protective layer 132 is formed. Prior to forming the first protective layer, the sidewall spacer 126 is removed. First protective layer 132 comprises a silicon nitride bottom protective layer 129 and a silicon dioxide top protective layer 130. Top and bottom protective layers 129 and 130 are deposited by CVD, ALD, PVD, or combinations thereof. First protective layer 132 and thinned oxide liner 124 are then patterned to form an opening 134 using conventional patterning techniques. Opening 134 exposes a surface of the underlying second silicon layer 104. Note that in another embodiment a portion of the underlying second silicon layer 104 is opening 134 may be removed during the patterning process.

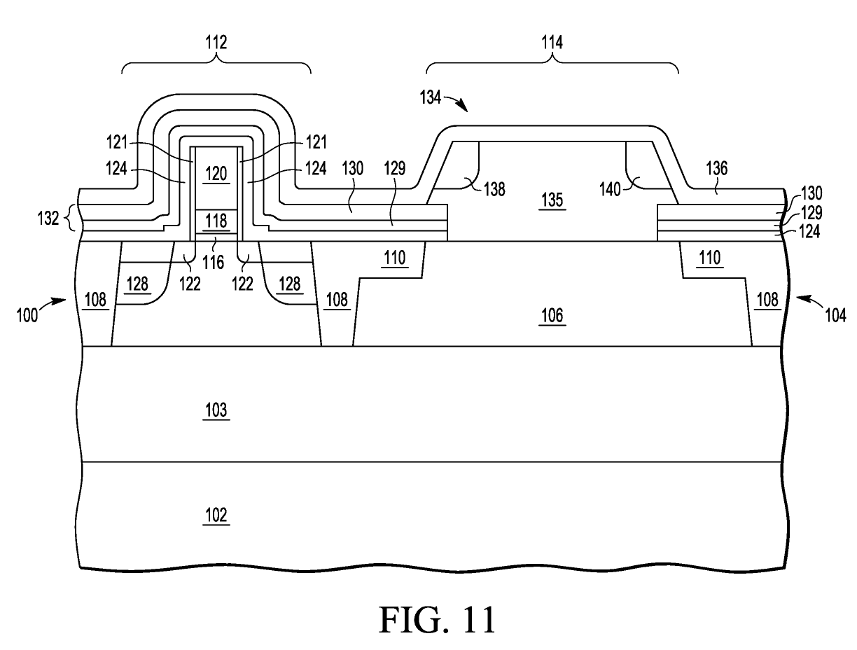

FIG. 11 illustrates cross-sectional views of semiconductor device 100 after a second protective layer 136 is formed. Prior to forming second protective layer 136, a semiconductor material 135 comprising germanium is formed in opening 134 to provide a photodetector. In one embodiment, semiconductor material 135 is germanium. Second protective layer 136 is a germanium protective layer. The germanium 135 is formed by epitaxial growth in opening 134 and preferably by selective epitaxial growth. Prior to the germanium growth process, it is desirable to perform a preclean so germanium can be grown better in opening 134. In one embodiment, the preclean exposes opening 134 to hydrogen for approximately 5 minutes at approximately 800 degrees Celsius. After the preclean, a germanium growth process is performed. During the germanium growth process, first protective layer 132 prevents germanium growth on the other areas of semiconductor device 100. In one embodiment, the germanium is grown by exposing semiconductor device 100 to a GeH₄ species at a temperature of approximately 400-600 degrees Celsius. Note that because the anneal temperature for the source/drain regions 128 is greater than the melting temperature of germanium, the anneal should be done before the germanium is grown. After forming the germanium 135, doped regions 138 and 140 are formed in portions of germanium 135. One of regions 138 and 140 will be doped N+ and the other P+. In one embodiment, semiconductor material 135 with dopant regions 138 and 140 form a photodetector device. In one embodiment, two mask and implant processes are used followed by one anneal process to form regions 138 and 140. The second protective layer 136 is then formed. Alternatively, doped regions 138 and 140 may be formed after the deposition of second protective layer 136. The second protective layer 136 can be formed by any process such as CVD, ALD, PVD and combinations thereof. In one embodiment, second protective layer 136 is a germanium protective layer that includes silicon and nitrogen, such as silicon nitride, silicon-rich silicon nitride, or silicon oxynitride.

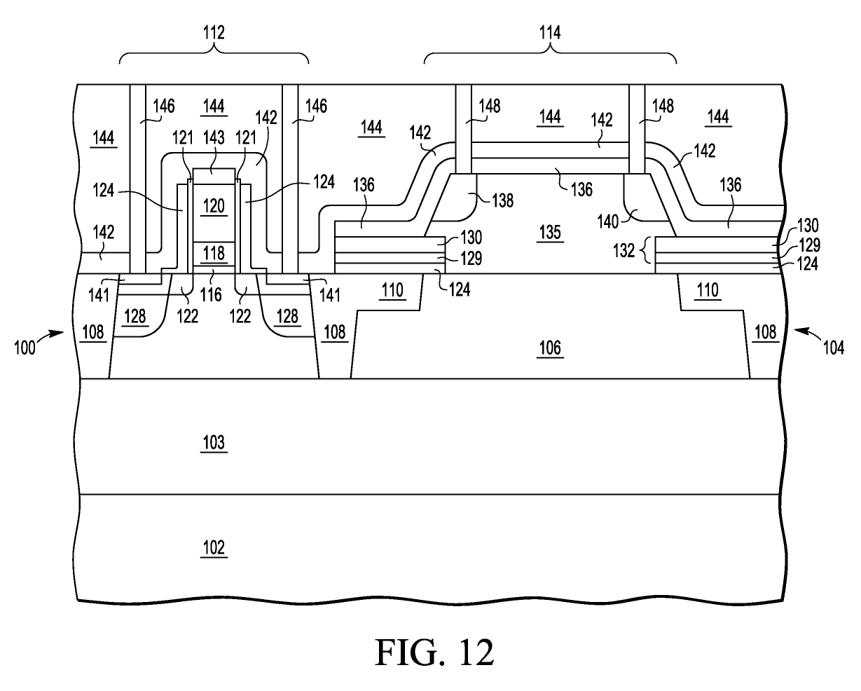

FIG. 12 illustrates a cross-sectional view of semiconductor device 100 after the first protective layer 132, the second protective layer 136, and the oxide layer 124 are patterned. The first and second protective layers and the oxide layer 124 only need to be removed for first isolation region 112 to allow for salicidation. The second protective layer 136 remains over germanium 135 to protect it from salicidation. The first and second protective layers 132 and 136 are removed from almost all portions of first isolation region 112. The oxide layer 124 is etched so that the thin residual oxide liner is removed while leaving a residual portion of the thicker part of oxide layer 124 as L-shaped sidewall structures on the gate as illustrated in FIG. 12. Sidewall spacers 121 also remain. After patterning the first and second protective layers, the exposed silicon portions of the first isolation region 112 are salicided to form salicide 141 in the source/drain regions 128 and salicide 143 on top of the gate stack. Note that as used herein, salicide means selective silicide or self-aligned silicide. Salicide 141 and 143 are formed by depositing a metal including nickel or platinum using CVD, ALD, PVD, or combinations thereof. Semiconductor device 100 is then heated to approximately 425 degrees Celsius or below in order for the nickel or platinum to react with the silicon in the gate electrode and in the source/drain regions. The salicide temperature for nickel and platinum is lower than the salicide temperatures of cobalt and lower than the anneal temperatures for doped regions 128.

A stressor layer 142 is then formed over semiconductor device 100. In one embodiment, stressor layer 142 is an etch stop layer (ESL) that provides compressive stress for P-channel transistors and relaxed stress for N-channel transistors. Silicon nitride may be used for a compressive stressor layer 142. The silicon nitride may be formed by CVD, ALD, PVD, or combinations thereof. An ILD layer 144 and contacts 146 and 148 are formed. The ILD layer 144 is formed and planarized using CMP. Contact openings are formed in ILD layer 144. In one embodiment, contacts 146 and 148 are formed from tungsten. In other embodiments, contacts 146 and 148 may be formed from another metal such as aluminum or copper.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method comprising:
providing a silicon substrate;
forming a first isolation region in the silicon substrate;
forming a second isolation region in the silicon substrate;
forming a gate electrode for a transistor in the first isolation region;
implanting source/drain extensions in the silicon substrate adjacent to the gate electrode;
forming a first sidewall spacer on a side of the gate electrode;
implanting source/drain regions in the silicon substrate adjacent to the gate electrode;
removing the first sidewall spacer from the side of the gate electrode;
forming a first protective layer over the first and second isolation regions of the silicon substrate;
removing a portion of the first protective layer to form an opening over the second isolation region;
forming a semiconductor material comprising germanium in the opening;
forming a second protective layer over the first and second isolation regions of the silicon substrate;
selectively removing the first and second protective layers from the first isolation region; and
forming contacts to the transistor and to the semiconductor material.

2. The method of claim 1, wherein providing a silicon substrate further comprises providing a silicon-on-insulator substrate.

3. The method of claim 1, wherein forming the first protective layer further comprises forming the first protective layer comprising silicon dioxide.

4. The method of claim 1, wherein forming the second protective layer further comprises forming the second protective layer comprising silicon nitride.

5. The method of claim 1, wherein forming a semiconductor material comprising germanium further comprises selectively depositing epitaxial germanium.

6. The method of claim 1, wherein selectively removing the first and second protective layers further comprises forming a second sidewall spacer on the gate electrode with a portion of the first protective layer.

7. The method of claim 6, further comprising selectively saliciding the source/drain regions and the gate electrode to form a salicide comprising a metal selected from a group consisting of nickel and platinum.

8. The method of claim 1, further comprising forming a stressor layer over the first isolation region after the step of selectively removing the first and second protective layers.

9. The method of claim 1, wherein forming the first protective layer further comprises:
forming a silicon nitride layer on the first and second isolation regions; and
forming a silicon dioxide layer on the silicon nitride layer.

10. The method of claim 1, wherein the first isolation region is formed using shallow trench isolation.

11. A method comprising:
providing a silicon substrate;
forming a first isolation region in the silicon substrate;
forming a second isolation region in the silicon substrate;
forming a gate electrode for a transistor in the first isolation region;
implanting source/drain extensions in the silicon substrate adjacent to the gate electrode;
forming a first sidewall spacer on a side of the gate electrode;
forming a second sidewall spacer adjacent to the first sidewall spacer, the second sidewall spacer being L-shaped;
forming a third sidewall spacer on the L-shaped second sidewall spacer;
implanting source/drain regions in the silicon substrate adjacent to the gate electrode;
removing the third sidewall spacer;
forming a first protective layer over the first and second isolation regions of the silicon substrate;
removing a portion of the first protective layer to form an opening over the second isolation region;
forming a semiconductor material comprising germanium in the opening;
forming a second protective layer over the first and second isolation regions of the silicon substrate;
selectively removing the first and second protective layers from the first isolation region; and
forming contacts to the transistor and to the semiconductor material.

12. The method of claim 11, wherein providing a silicon substrate further comprises providing a silicon-on-insulator substrate.

13. The method of claim 11, wherein forming the first protective layer further comprises forming the first protective layer comprising silicon dioxide.

14. The method of claim 11, wherein forming the second protective layer further comprises forming the second protective layer comprising silicon nitride.

15. The method of claim 11, wherein forming a semiconductor material comprising germanium further comprises selectively depositing epitaxial germanium.

16. The method of claim 11, further comprising selectively saliciding the source/drain regions and the gate electrode to form a salicide comprising a metal selected from a group consisting of nickel and platinum.

17. The method of claim 11, further comprising forming a stressor layer over the first isolation region after the step of selectively removing the first and second protective layers.

18. The method of claim 11, wherein forming the first protective layer further comprises:
forming a silicon nitride layer on the first and second isolation regions; and
forming a silicon dioxide layer on the silicon nitride layer.

19. The method of claim 11, wherein the first and second isolation regions are formed using shallow trench isolation.

20. The method of claim 11, further comprising forming doped regions in the semiconductor material comprising germanium.
